(19) United States
(12) Patent Application Publication
(10) Pub. No.: US 2006/0062901 A1
(43) Pub. Date: Mar. 23, 2006

(54) FABRICATION METHOD OF FRONT SUBSTRATE OF PLASMA DISPLAY, EVAPORATION PROCESS AND EVAPORATION APPARATUS

(76) Inventor: Kuo-Ching Chou, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,076

(22) Filed: Aug. 29, 2005

(30) Foreign Application Priority Data
Sep. 21, 2004 (TW) 93128507

(51) Int. Cl. B05D 5/06; C23C 8/00; B05D 5/12; C23C 16/00

(52) U.S. Cl. 427/64; 427/77; 427/585; 118/726

(57) ABSTRACT

An evaporation apparatus including a vacuum chamber, a gas pipe, an evaporation source and a gas pump is provided. The gas pipe disposed in the vacuum chamber has a plurality of holes. A flow rate of reactive gas, which flows through a part of the plurality of holes adjacent to the pump, is higher than that flowing through the other holes to compensate the gases being pumped out by the gas pump, so as to form a film with a good crystalline uniformity.

### CROSS-REFERENCE TO RELATED APPLICATION

This application claims the priority benefit of Taiwan application serial no. 93128507, filed on Sep. 21, 2004. All disclosure of the Taiwan application is incorporated herein by reference.

### BACKGROUND OF THE INVENTION

1. Field of the Invention

The present invention relates to a process of forming a thin film and a process apparatus, and more particularly to a fabrication process of a front substrate of a plasma display panel, an evaporation process and an evaporation apparatus.

2. Description of Related Art

With advancement of technologies, displays serving as interfaces between users and machines have become increasingly important. Gradually, panel displays are replacing traditional cathode ray tube displays. Flat displays usually include plasma displays, OLED and liquid crystal displays (LCD). With big screen sizes, self-illumination, wide view angle, slim and full color, plasma displays could become the main stream for the next generation displays.

The prior art plasma display includes a front substrate, a rear substrate and discharging gases. FIG. 1 is a schematic 3D drawing showing a prior art plasma display. Referring to FIG. 1, the plasma display panel 100 includes a front substrate 110, a rear substrate 120 and a reactive gas (not shown) between the front substrate 110 and the rear substrate 120. The front substrate 110 includes a substrate 112, a plurality of X electrodea 114, a plurality of Y electrodes, a dielectric layer 118 and a passivation layer 119. Each X electrode 114 includes a transparent electrode 114a and a bus electrode 114b. Each Y electrode 116 includes a transparent electrode 116a and a bus electrode 116b. In the prior art plasma display panel, the material of the transparent electrodes 114a and 116a is indium tin oxide (ITO). Due to its lower conductivity than that of metal, metal bus electrodes 114b and 116b are disposed on the transparent electrodes 114a and 116a, respectively, for increasing the conductivity of the X electrodes 114 and the Y electrodes 116. The bus electrodes 114b and 116b, which are located outside of the illumination area, will not affect the illumination efficiency of the plasma display panel.

The dielectric layer 118 is disposed on the substrate 112, covering the X electrodes 114 and the Y electrodes 116. The passivation layer 119 is disposed on the dielectric layer 118 for protecting the X electrodes 114 and the Y electrodes 116, such that damage of the X electrodes 114 and the Y electrodes 116 are reduced during discharging in the plasma display panel.

The rear substrate 120 includes a substrate 122, a plurality of address electrodes 124, a dielectric layer 126, a rib 128 and a fluorescent material layer 129. The address electrodes 124 are disposed on the substrate 122. The dielectric layer 126 is disposed on the substrate 122, covering the address electrodes 124. Generally, the rib 128 is disposed between two address electrodes 124 to define a plurality of discharging spaces 127. The fluorescent material layer 129 is disposed on the dielectric layer 126 in the discharging spaces 127, covering the sidewalls of the rib 128. The discharging gases (not shown) are filled within the discharging spaces 127.

In order to maintain high quality of images, the plasma display panel requires stable discharging characteristics. The uniformity of the passivation layer 119 affects the discharging characteristics of the plasma display panel. Accordingly, forming a passivation layer 119 with desired crystal uniformity is an important issue in this industry.

Electron beam evaporation deposition has been widely used to form the passivation layer of the front substrate. Generally, the material of the passivation layer is magnesium oxide (MgO). FIG. 2A is a schematic cross sectional drawing of a prior art evaporation apparatus 200. FIG. 2B is a schematic top-view drawing of a prior art evaporation apparatus 200. Referring to FIGS. 2A-2B, the front substrate 110 having X electrodes 114 and Y electrodes 116 shown in FIG. 1 is provided in the chamber 208. The electron gun 202 ejects the electron beam 204 for heating the evaporation material 206. At this time, the evaporation material 206 composed of magnesium oxide (MgO) is converted from solid state to gaseous state to provide oxygen ion and magnesium ion.

Due to the deposition rate of magnesium ion is higher than that of oxygen ion, oxygen ion is pumped out easily from the chamber 208 via the gas pumps 212 (shown in FIG. 2B). Therefore, the ratio of oxygen ion and magnesium ion of the magnesium oxide film formed on the front substrate 110 is not 1:1.

In order to solve the problem mentioned above, a reactive gas including oxygen ion is provided by a gas supply apparatus 205 and conducted into the chamber 208 via the holes 210 of the gas pipe 209, while the evaporation material 206 is heated by the electron beam 204. The reactive gas including oxygen ion is provided to compensate oxygen ion pumped out from the chamber 208 via the gas pumps 212, such that the ratio of oxygen ion and magnesium ion of the magnesium oxide film formed on the front substrate 110 is 1:1.

When the reactive gas is provided into the chamber 208 via the holes 210, which is located near the gas pumps 212, the reactive gas can be easily pumped out from the chamber 208 via the gas pumps 212 before reacting with the molecules of the evaporation material 206. As a result, the amount of the reactive gas at the area near the gas pumps 212 is less than that at the other area. This phenomenon results in crystal non-uniformity of the passivation layer 119 formed on the front substrate 110.

An X-ray diffractometer is used to identify crystal uniformity of the passivation layer 119 by performing crystal diffraction. From experiments, the more uniform the crystallization of the thin film, the higher the peak of the diffraction pattern is. It should be noted that the flow rate of the reactive gas, which is provided during deposition of the thin film, affects the peak intensity of the diffraction pattern. The relationship curve is shown in FIG. 3. Referring to FIG. 3, the flow rate of the reactive gas, which is provided during deposition of the thin film, is proportional to the peak intensity of the diffraction pattern. In other words, the flow rate of the reactive gas must be controlled in a reasonable range so as to from a thin film with excellent crystal uniformity.

### SUMMARY OF THE INVENTION

Accordingly, the present invention is directed to an evaporation apparatus. Under the fixed amount of the reactive gas, the amount of reactive gas in an area of the chamber is greater than that in the other area of the chamber for forming a desired crystal uniformity of a film.

The present invention is directed to a fabrication method of a front substrate of a plasma display panel. By improving crystal uniformity of the passivation layer, the discharging stability of the plasma display panel is thus enhanced.

The present invention is also directed to a fabrication process of forming a film with excellent crystal uniformity.

The present invention discloses an evaporation apparatus. The evaporation apparatus includes a chamber, a gas pipe, an evaporation source and a gas pump. The gas pipe is disposed in the chamber and has a plurality of holes. The holes are adapted to conduct a reactive gas into the chamber. The evaporation source is disposed in the chamber. The gas pump is disposed on at least two sides of the chamber. A flow rate of a reactive gas from the holes, which are adjacent to the gas pump, is greater than that from the other holes.

According to an embodiment of the present invention, the holes include a plurality of first holes and a plurality of second holes. In one embodiment, the first holes are more than the second holes, and the first holes are smaller than, equal to or larger than the second holes. In another embodiment, the first holes are larger than the second holes, and the number of the first holes are less than or equal to the number of the second holes. The shape of the first holes and the second holes are round, elliptical, polygon or irregular.

According to an embodiment of the present invention, the evaporation source includes, for example, an evaporation material carrier and a heater. The evaporation material carrier is adapted to carry an evaporation material. The heater is adapted to heat the evaporation material. In one embodiment, the heater can be, for example, an electron gun.

According to an embodiment of the present invention, the spaces between the holes gradually increase from the gas pump to the center of the chamber. In another embodiment, the sizes of the holes gradually increase from the center of the chamber to the gas pump.

The present invention also discloses a fabrication method of a front substrate of a plasma display panel. First, a plurality of pairs of electrodes is formed on a substrate. Next, the substrate is provided in a chamber. The chamber includes an evaporation material therein and is connected to a gas pump. The evaporation material is heated and vaporized. A reactive gas is provided into the chamber. Vaporized molecules of the evaporation material react with the reactive gas to form a film (passivation layer) covering the pairs of electrodes on the substrate. A flow rate of the reactive gas conducted to the position adjacent to the gas pump is greater than that of the other positions.

The present invention further discloses an evaporation process adapted to form a film over a substrate in a chamber. The chamber has an evaporation material therein and one side of the chamber is connected to a gas pump. First, the evaporation material is heated and vaporized. A reactive gas is provided into the chamber. Vaporized molecules of the evaporation material react with the reactive gas for forming a passivation layer covering the pairs of electrodes on the substrate. A flow rate of the reactive gas conducted to the position adjacent to the gas pump is greater than that of the other positions.

According to an embodiment of the present invention, the evaporation material is heated by an electron beam. In one embodiment, a dielectric layer is formed for covering the pairs of the electrodes before the passivation layer is formed.

As described above, the present invention improves the crystal uniformity of the film without increasing the amount of the reactive gas.

The above and other features of the present invention will be better understood from the following detailed description of the preferred embodiments of the invention that is provided in connection with the accompanying drawings.

### BRIEF DESCRIPTION OF THE DRAWINGS

FIG. 1 is an exploded view showing a prior art plasma display.

FIG. 2A is a schematic cross sectional view of a prior art evaporation apparatus.

FIG. 2B is a schematic top-view of a prior art evaporation apparatus.

FIG. 3 is a view showing a relationship between the flow rate of the reactive gas with the peak intensity of the diffraction pattern of the film.

FIG. 4 is a schematic top-view showing an evaporation apparatus according to an embodiment of the present invention.

FIGS. 5, 6A-6B and 7 are schematic top-views of an evaporation apparatus according to an embodiment of the present invention.

FIGS. 8A and 8B are cross sectional views showing the progression steps of a method of fabricating a front substrate of a plasma display panel according to an embodiment of the present invention.

### DESCRIPTION OF SOME EMBODIMENTS

The present invention is related to an improvement of a gas pipe of an evaporation apparatus for enhancing crystal uniformity of a film. Following are the descriptions of the embodiment according to the present invention. The present invention, however, is not limited thereto. One of ordinary skill in the art may amend the embodiment according to the present invention. Such amendment still falls within the scope of the invention.

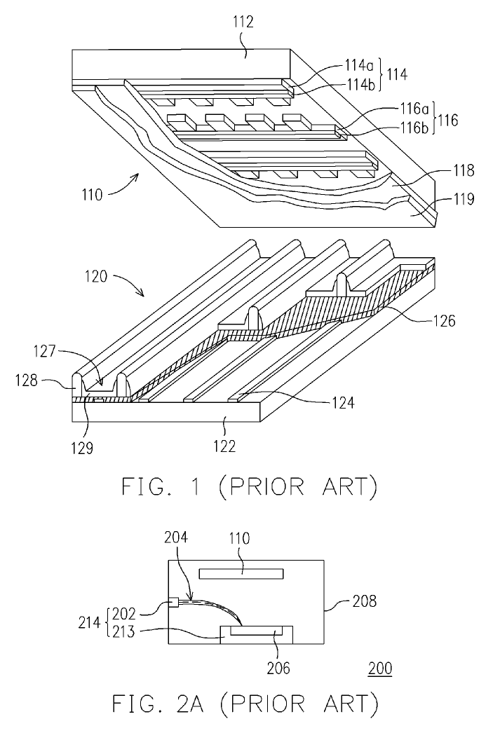

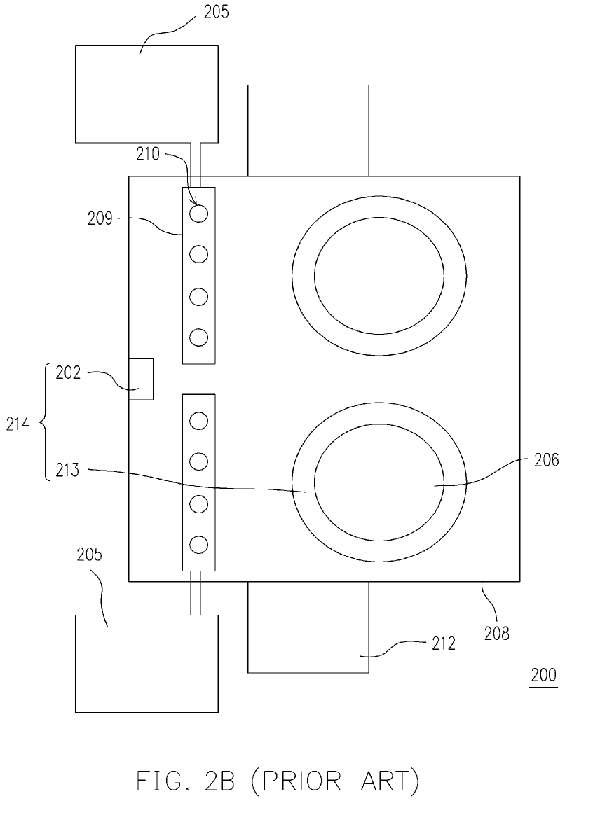

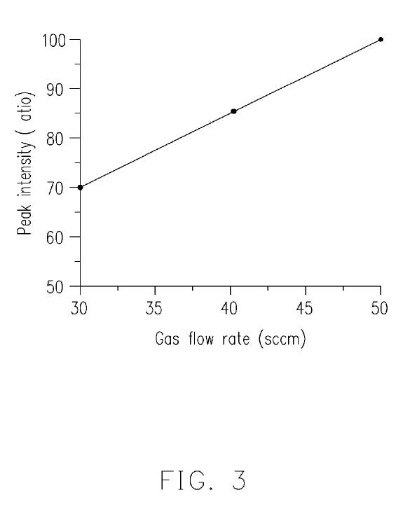

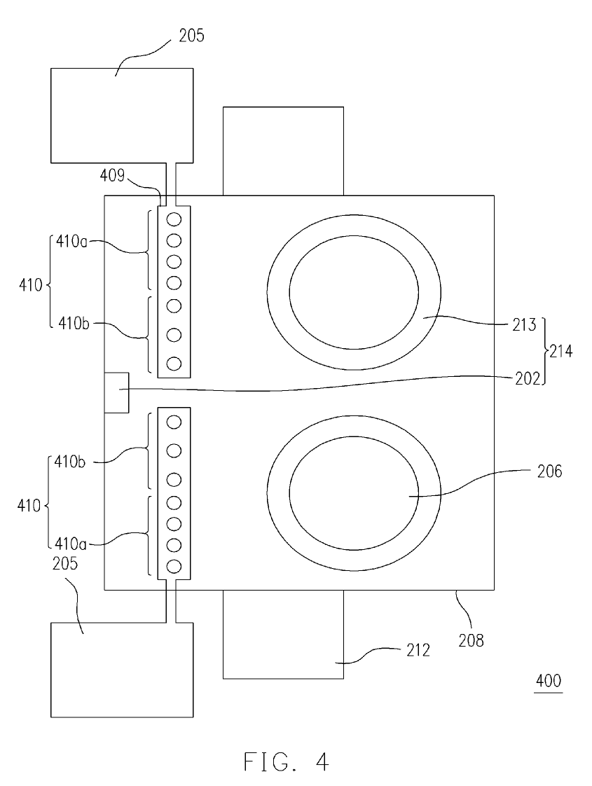

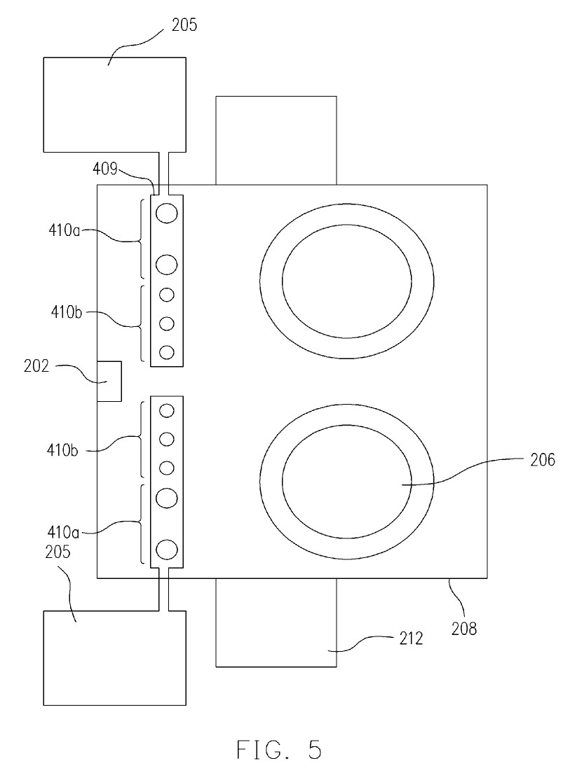

FIG. 4 is a schematic top-view showing evaporation apparatus according to an embodiment of the present invention. FIG. 2A is a schematic cross sectional view of an evaporation apparatus according to an embodiment of the present invention.

Referring to FIGS. 2A and 4, an evaporation apparatus 400 includes a chamber 208, a gas pipe 409, an evaporation source 214 and a gas pump 212. The evaporation source 214 is disposed in the chamber 208. The evaporation source 214 includes, for example, an evaporation material carrier 213 and a heater 202. The evaporation material carrier 213 is disposed, for example, in the chamber 208 for carrying the evaporation material 206. The heater 202 is adapted to heat the evaporation material 206. In this embodiment, the evaporation material 206 can be, for example, MgO or other suitable material. The heater can be, for example, an electron gun. In other words, in this embodiment, the evaporation material 206 is heated by the electron beam 204 ejected from the heater 202 as shown in FIG. 2A.

The gas pipe 409 includes a plurality of holes 410 for conducting a reactive gas (not shown) from the gas supply apparatus 205 to the chamber 208 during the evaporation process. In this embodiment, the reactive gas can be, for example, oxygen. It means that the film formed in this embodiment is MgO layer. In this embodiment, the evaporation apparatus 400 includes, for example, at least two gas pumps 212, which are connected to at least two sides of the chamber 208. The gas pumps 212 are used to maintain the chamber 208 in a vacuum. The holes include, for example, first holes 410a and second holes 410b. The first holes are located adjacent to the gas pumps 212. In this embodiment, the number of the first holes 410a is greater than that of the second holes 410b. Accordingly, more reactive gas is provided to the area adjacent to the gas pumps 212 to compensate the amount of the reactive gas that were pumped out from the chamber 208 by the gas pumps 212 before reaction. The size of the first inlets 410a can be smaller than, equal to, or larger than that of the second holes 410b. In this embodiment, the sizes of the first holes 410a and the second holes 410b are not limited.

In another embodiment, the size of the first holes 410a is larger than that of the second holes 410b. Accordingly, more reactive gas is provided at the area adjacent to the gas pumps 212. In this embodiment, the number of the first holes 410a can be less than, equal to, or more than that of the second holes 410b. This embodiment does not limit the numbers of the first holes 410a and the second holes 410b.

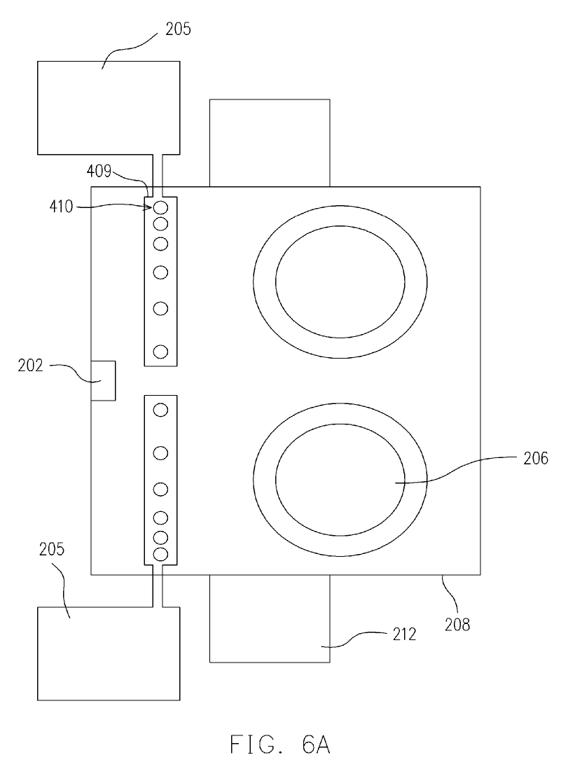

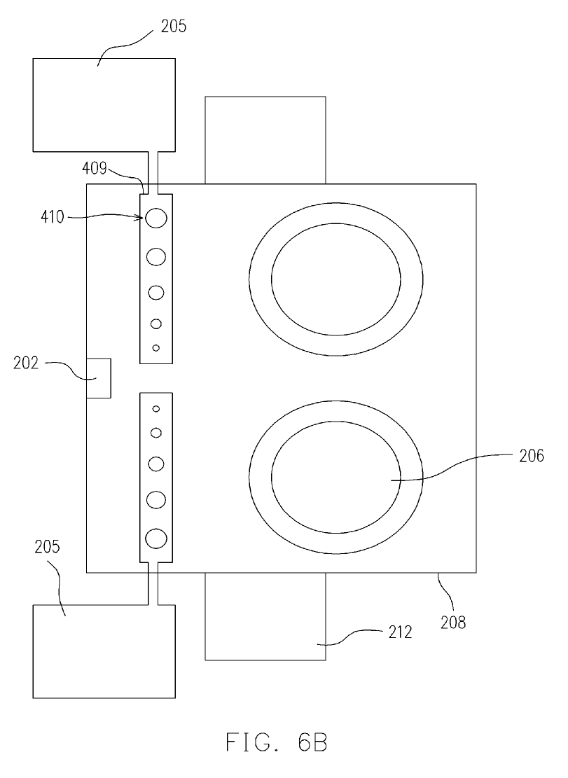

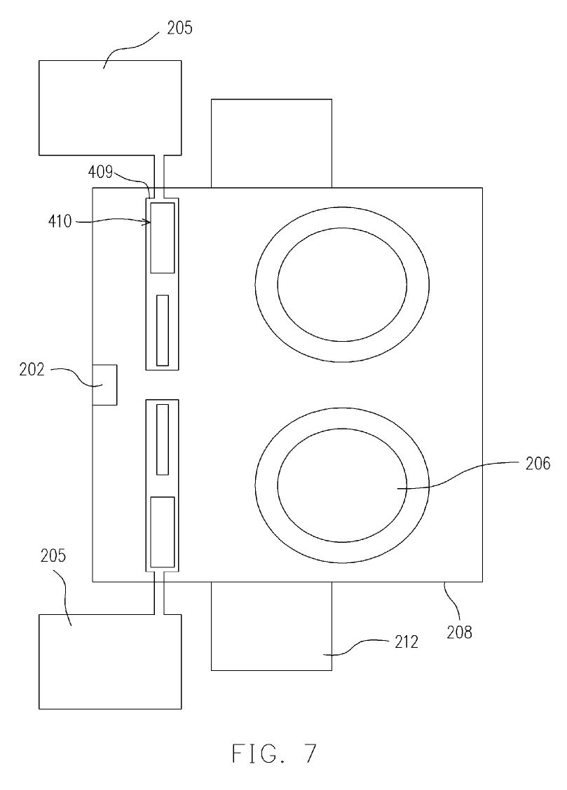

In addition, the spaces between the holes 410 can gradually increase or decrease. For example, the spaces between the holes 410 gradually decrease from the center toward the gas pumps 212 as shown in FIG. 6A. Furthermore, the present invention may gradually enlarge or shrink the sizes of the holes 410 as shown in FIG. 6B. The shape of the holes 410 can be round, rectangular (as shown in FIG. 7), elliptical, irregular or polygon. The present invention does not limit the shape of the holes 410. One ordinary skill in the art may determine the shape based on requirements.

Following are the descriptions of the process of the front substrate of the plasma display panel to interpret the evaporation process of the present invention.

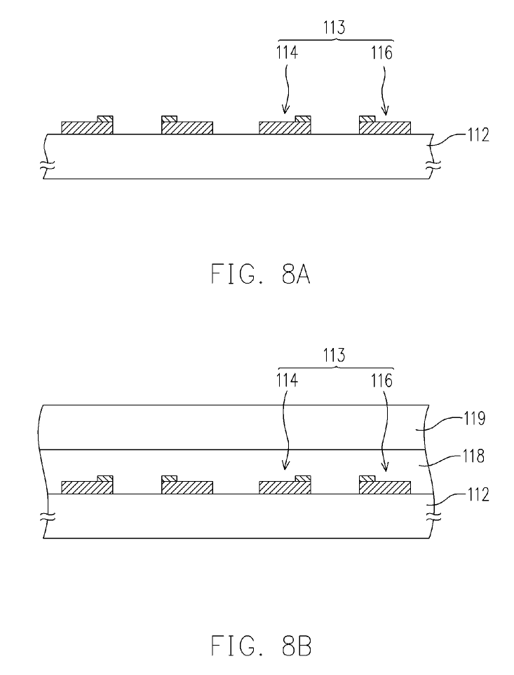

FIGS. 8A and 8B are cross sectional views showing the progression steps of a method of fabricating a front substrate of a plasma display panel according to an embodiment of the present invention. An exploded view of the front substrate of the plasma display panel can be represented by FIG. 1. The same drawing is not repeated.

Referring to FIG. 8A, a plurality of pairs of electrodes 113 is formed on the substrate 112. Each of the pairs of the electrodes 113 includes an X electrode 114 and a Y electrode 116. Referring to FIG. 8B, a passivation layer 119 is formed on the substrate 112. In this embodiment, a dielectric layer 118 is formed over the pairs of the electrodes 113 and the substrate 112 before the formation of the passivation layer 119. Next, the passivation layer 119 is formed over the dielectric layer 118. The method of forming the passivation layer 119 includes, for example, providng the substrate 112 with the pairs of the electrodes 113 thereon in a chamber. The chamber can be, for example, a vacuum chamber. An evaporation material is heated and vaporized in the chamber while the reactive gas is provided therein. Vaporized molecules of the evaporation material react with the reactive gas to form the passivation layer 119 over the substrate 112. In the evaporation process, the temperature of the substrate 112 can be, for example, about 200° C. The deposition rate of the passivation layer 119 can be, for example, about 3.8 nm/s.

In this embodiment, the chamber is connected to the gas pumps, which is shown in FIG. 4, for maintaining the chamber in a vacuum. It is noted that the flow rate of the reactive gas conducted to the position adjacent to the gas pumps is greater than that of the other positions so as to compensate the amount of the gas that was pumped out of the chamber before reaction. In this embodiment, the evaporation material can be, for example, MgO. The reactive gas can be, for example, oxygen. In other words, the passivation layer 119 can be, for example, a MgO layer.

Accordingly, the evaporation apparatus of the present invention provides more reactive gas at the area adjacent to the gas pumps than the other area by modifying the design of the holes. With the modification, the reactive gas that was pumped out by the gas pump before reaction can be compensated. The overall crystallization difference is reduced and the crystal uniformity of the thin film formed by the evaporation process is thus improved. From experiments, the crystal uniformity of the film of the present invention is improved by 15%-20%. As described above, the evaporation apparatus, according to an embodiment of the present invention, can improve the crystal uniformity of the film without increasing the amount of the reactive gas. Therefore, the present invention can improve the quality of the film without increasing manufacturing costs. Moreover, the present invention uses the evaporation apparatus to form the passivation layer on the front substrate of the plasma display panel. The passivation layer has better crystal uniformity and improves discharging stability of the plasma display panel. Better image qualities are thus obtained.

In addition, the evaporation process of the present invention provides more reactive gas at the area adjacent to the gas pumps than at the other area by controlling the flow rate of the reactive gas. By such controlling, the reactive gas that was pumped out by the gas pump before reaction can be compensated. The crystal uniformity of the thin film form by the evaporation process is thus improved.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. An evaporation apparatus, comprising:
a chamber;
a gas pipe, disposed in the chamber, wherein the gas pipe has a plurality of holes;
an evaporation source, disposed in the chamber; and
a gas pump, disposed on a side of the chamber, wherein a flow rate of a reactive gas from the holes adjacent to the gas pump is greater than that from the other holes.

2. The evaporation apparatus of claim 1, wherein spaces between the holes gradually increase from the gas pump to the center of the chamber.

3. The evaporation apparatus of claim 1, wherein sizes of the holes gradually increase from the center of the camber to the gas pump.

4. The evaporation apparatus of claim 1, wherein the plurality of holes comprise a plurality of first holes and a plurality of second holes, and the first holes are closer to the gas pump than the second holes.

5. The evaporation apparatus of claim 4, wherein a number of the first holes is greater than that of the second holes.

6. The evaporation apparatus of claim 5, wherein a size of the first holes is substantially equal to that of the second holes.

7. The evaporation apparatus of claim 5, wherein a size of the first holes is smaller than that of the second holes.

8. The evaporation apparatus of claim 5, wherein a size of the first holes is larger than that of the second holes.

9. The evaporation apparatus of claim 4, wherein a size of the first holes is larger than that of the second holes.

10. The evaporation apparatus of claim 9, wherein a number of the first holes is equal to that of the second holes.

11. The evaporation apparatus of claim 9, wherein a number of the first holes is less than that of the second holes.

12. The evaporation apparatus of claim 1, wherein a shape of the holes is round, elliptical, polygon or irregular.

13. The evaporation apparatus of claim 1, wherein the evaporation source comprises an evaporation material carrier and a heater for heating the evaporation material.

14. The evaporation apparatus of claim 13, wherein the heater comprises an electron gun.

15. A method of fabricating a front substrate of a plasma display panel, comprising:
forming a plurality of pairs of electrodes on a substrate; and
transferring the substrate in a chamber connected to a gas pump, the chamber comprising an evaporation material therein;
heating and vaporizing the evaporation material; and
charging a reactive gas into the chamber, such that vaporized molecules of the evaporation material react with the reactive gas to form a passivation layer covering the pairs of electrodes on the substrate, wherein a flow rate of the reactive gas conducted to the position adjacent to the gas pump is greater than that of the other positions to improve crystal uniformity of the passivation layer.

16. The method of claim 15, wherein the evaporation material is heated and vaporized by an electron beam.

17. The fabrication method of claim 15, further comprising:
forming a dielectric layer over the substrate for covering the pairs of the electrodes after the pairs of the electrodes are formed on the substrate but before the passivation layer are formed on the substrate.

18. The method of claim 15, wherein a substrate temperature is about 200° C. during a process of forming the passivation layer on the substrate.

19. The method of claim 15, wherein a deposition rate of forming the passivation layer is about 3.8 nm/s.

20. An evaporation process for forming a film over a substrate in a chamber, wherein the chamber comprises an evaporation material therein, and a side of the chamber connects to a gas pump, the evaporation process comprising:
heating and vaporizing the evaporation material; and
providing a reactive gas into the chamber, such that vaporized molecules of the evaporation material react with the reactive gas to form a passivation layer covering the pairs of electrodes on the substrate, wherein a flow rate of the reactive gas conducted to the position adjacent to the gas pump is greater than that of the other positions to improve crystal uniformity of the passivation layer.

21. The process of claim 20, wherein the evaporation material is heated and vaporized by an electron beam.
